(19) United States
(12) Patent Application Publication
(10) Pub. No.: US 2023/0134971 A1
(43) Pub. Date: May 4, 2023

(54) Method Of Fabricating Epitaxial Source/Drain Feature

(71) Applicant: Taiwan Semiconductor Manufacturing Company, Ltd., Hsin-Chu (TW)

(72) Inventors: Wei-Han Fan, Hsin-Chu City (TW); Chia-Pin Lin, Hsinchu County (TW); Wei-Yang Lee, Taipei City (TW); Tzu-Hua Chiu, Hsinchu (TW); I-Hsieh Wong, Hsinchu (TW); Alex Lee, Hsinchu (TW)

(21) Appl. No.: 17/873,773

(22) Filed: Jul. 26, 2022

Related U.S. Application Data
(60) Provisional application No. 63/274,212, filed on Nov. 1, 2021.

(51) Int. Cl. H01L 29/78; H01L 29/08; H01L 27/092; H01L 21/8238

(52) U.S. Cl. CPC H01L 29/7848; H01L 29/0847; H01L 27/092; H01L 21/823814; H01L 29/42392

(57) ABSTRACT

Source/drain epitaxial features and methods for fabricating such are disclosed herein. An exemplary method includes receiving a substrate including a n-type region and a p-type region, forming a stack of semiconductor layers over the substrate, the stack of semiconductor layers including interleaving first material layers and second material layers, and performing an etch process to form a first source/drain recess in the n-type region and a second source/drain recess in the p-type region. The method further includes depositing a metal-containing layer over the stack of semiconductor layers, including within the first source/drain recess and the second source/drain recess, removing the metal-containing layer from the n-type region, and forming an n-type epitaxial source/drain feature in the first source/drain recess. The method further includes removing the metal-containing layer from the p-type region and forming a p-type epitaxial source/drain structure in the second source/drain recess.

### PRIORITY DATA

This application claims the benefit of U.S. Provisional Application No. 63/274,212, filed Nov. 1, 2021, which is hereby incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Recently, multigate devices have been introduced to improve gate control. Multigate devices have been observed to increase gate-channel coupling, reduce OFF-state current, and/or reduce short-channel effects (SCEs). One such multigate device is the gate-all around (GAA) device, which includes a gate structure that can extend, partially or fully, around a channel region to provide access to the channel region on at least two sides. GAA devices enable aggressive scaling down of IC technologies, maintaining gate control and mitigating SCEs, while seamlessly integrating with conventional IC manufacturing processes. As GAA devices continue to scale, challenges have arisen with stressed caused by manufacturing epitaxial source/drain features which degrade performance of the GAA devices.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a flowchart of an example method for fabricating a semiconductor device according to various embodiments of the present disclosure.

FIG. 2A is a three-dimensional perspective view of an example semiconductor device according to various embodiments of the present disclosure.

FIG. 2B is a planar top view of the semiconductor device shown in FIG. 2A according to various embodiments of the present disclosure.

FIGS. 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, and 30A are cross-sectional views of the semiconductor device shown in FIGS. 2A and 2B taken along line AA′ at intermediate stages of the example of FIGS. 1A and 1B according to various embodiments of the present disclosure.

FIGS. 3B, 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, and 30B are cross-sectional views of the semiconductor device shown in FIGS. 2A and 2B taken along line BB′ at intermediate stages of the example method of FIGS. 1A and 1B according to various embodiments of the present disclosure.

FIGS. 3C, 4C, 5C, 6C, 7C, 8C, 9C, 10C, 11C, 12C, 13C, 14C, 15C, 16C, 17C, 18C, 19C, 20C, 21C, 22C, 23C, 24C, 25C, 26C, 27C, 28C, 29C, and 30C are cross-sectional views of the semiconductor device shown in FIGS. 2A and 2B taken along line CC′ at intermediate stages of the example method of FIGS. 1A and 1B according to various embodiments of the present disclosure.

### DETAILED DESCRIPTION

The present disclosure relates generally to integrated circuit devices, and more particularly, to multigate devices, such as gate-all-around (GAA) devices.

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

Further, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used herein for ease of description to describe one element or feature's relationship to another element(s) or feature(s). The spatially relative terms are intended to encompass different orientations than as depicted of a device (or system or apparatus) including the element(s) or feature(s), including orientations associated with the device's use or operation. The apparatus may be otherwise oriented (rotated 90 degrees or at other orientations) and the spatially relative descriptors used herein may likewise be interpreted accordingly.

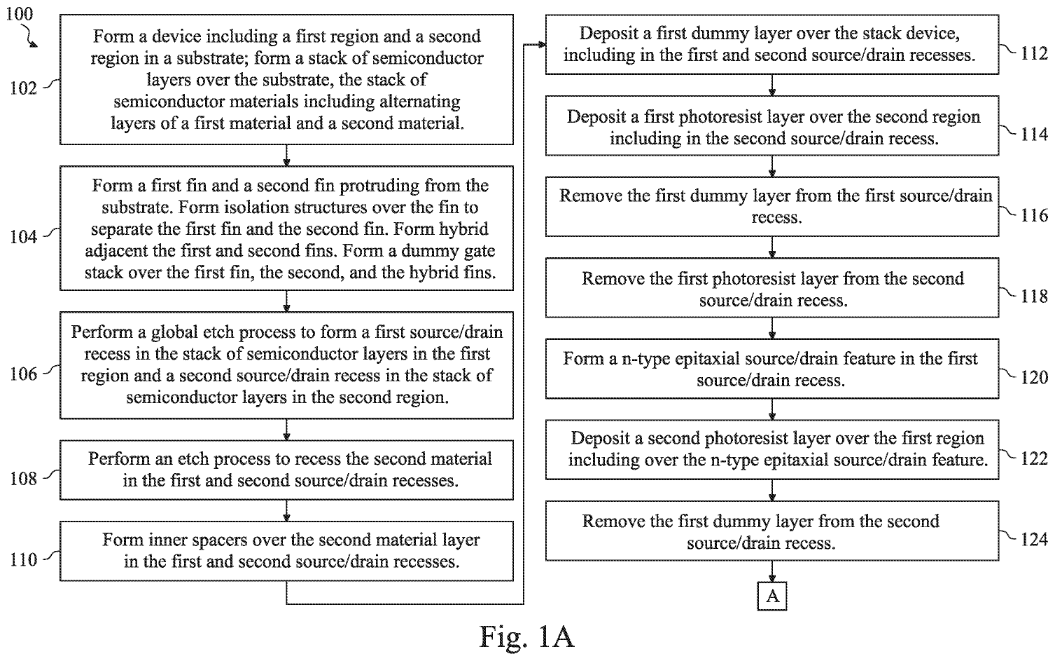

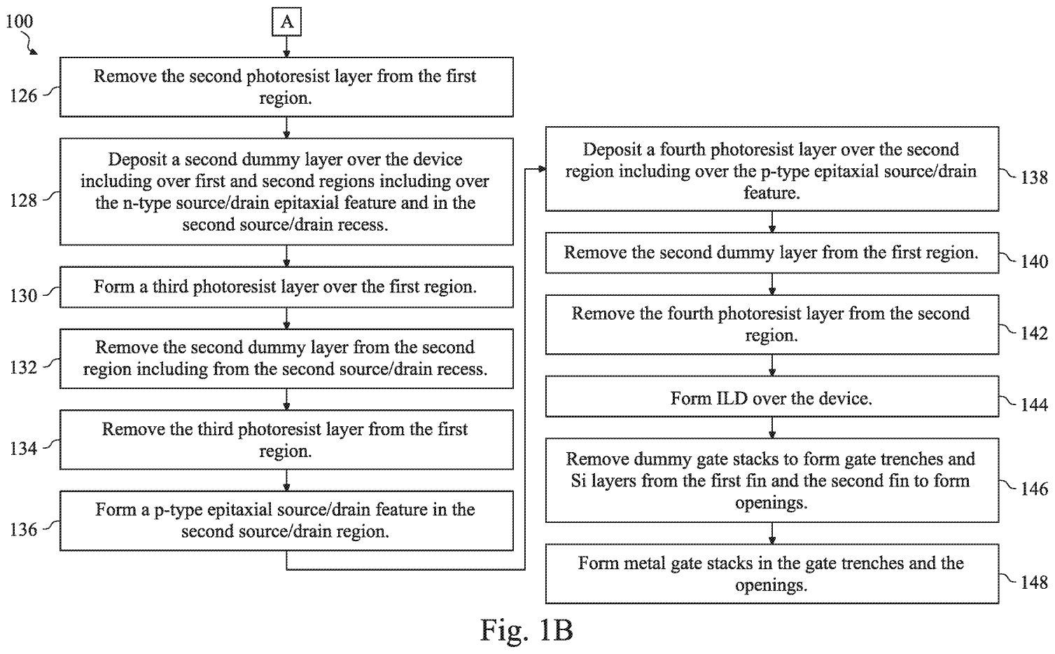

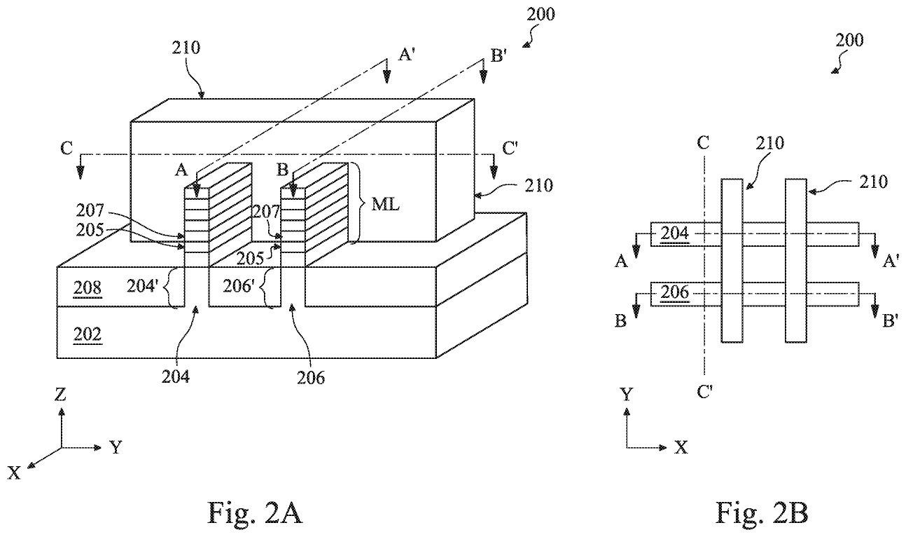

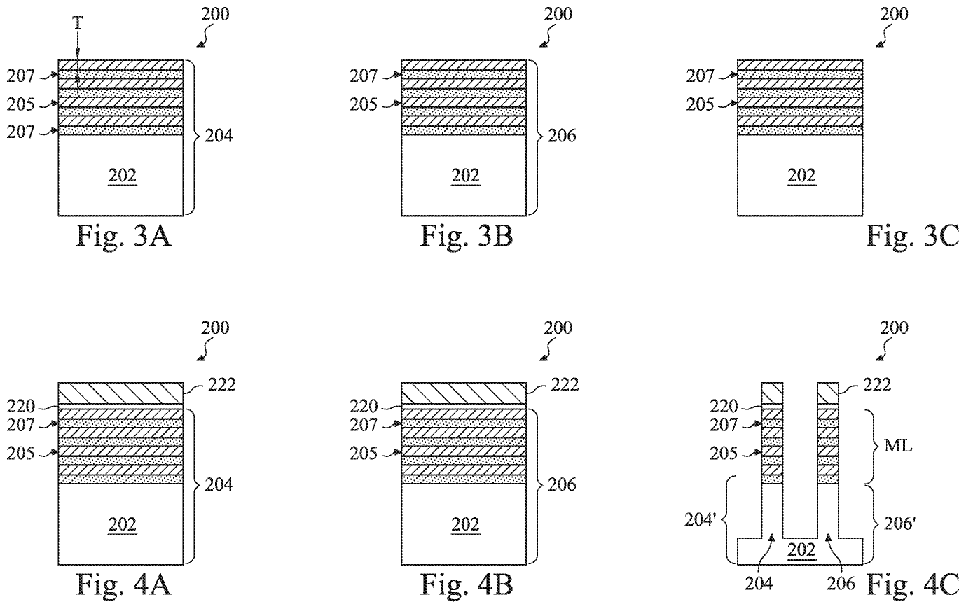

Referring now to FIGS. 1A and 1B, flowchart of method 100 of forming a semiconductor device (hereafter referred to as the device) 200 are illustrated according to various aspects of the present disclosure. Method 100 is merely an example and is not intended to limit the present disclosure beyond what is explicitly recited in the claims. Additional operations can be provided before, during, and after method 100, and some operations described can be replaced, eliminated, or moved around for additional embodiments of the method. Method 100 is described below in conjunction with FIGS. 2A-30C, where FIG. 2A is a three-dimensional perspective view, FIG. 2B is a planar top view, and FIGS. 3A-30C are cross-sectional views taken through various regions of the device 200 as depicted in FIGS. 2A and 2B at intermediate steps of method 100. Specifically, FIGS. 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, and 30A are cross-sectional views along line AA′ taken through a fin active region (hereafter referred to as the fin) 204 of the device 200, FIGS. 3B, 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, and 30B are cross-sectional views along line BB′ taken through a fin 206 of the device 200, and FIGS. 3C, 4C, 5C, 6C, 7C, 8C, 9C, 10C, 11C, 12C, 13C, 14C, 15C, 16C, 17C, 18C, 19C, 20C, 21C, 22C, 23C, 24C, 25C, 26C, 27C, 28C, 29C, and 30C are cross-sectional views along line CC′ taken through source/drain (S/D) regions of the fin 204 and the fin 206.

The device 200 may be an intermediate device fabricated during processing of an IC, or a portion thereof, that may comprise static random-access memory (SRAM) and/or other logic circuits, passive components such as resistors, capacitors, and inductors, and active components such as GAA FETs, FinFETs, MOSFETs, CMOSFETs, bipolar transistors, high voltage transistors, high frequency transistors, and/or other transistors. The present disclosure is not limited to any particular number of devices or device regions, or to any particular device configurations. Additional features can be added to the device 200, and some of the features described below can be replaced, modified, or eliminated in other embodiments of the device 200.

Referring to FIGS. 2A, 2B, and 3A-3C, method 100 at operation 102 provides a semiconductor substrate (hereafter referred to as “the substrate”) 202 and subsequently forms a multi-layered structure (ML) thereover. The substrate 202 may include an elemental (i.e., having a single element) semiconductor, such as silicon (Si), germanium (Ge), or other suitable materials; a compound semiconductor, such as silicon carbide, gallium arsenic, gallium phosphide, indium phosphide, indium arsenide, indium antimonide, other suitable materials, or combinations thereof; an alloy semiconductor, such as SiGe, GaAsP, AlInAs, AlGaAs, GaInAs, GaInP, GaInAsP, other suitable materials, or combinations thereof. The substrate 202 may be a single-layer material having a uniform composition. Alternatively, the substrate 202 may include multiple material layers having similar or different compositions suitable for manufacturing the device 200.

In some examples where the substrate 202 includes FETs, various doped regions may be disposed in or on the substrate 202. The doped regions may be doped with n-type dopants, such as phosphorus or arsenic, and/or p-type dopants, such as boron or BF2, depending on design requirements. The doped regions may be formed directly on the substrate 202, in a p-well structure, in an n-well structure, in a dual-well structure, or in a raised structure. Doped regions may be formed by implantation of dopant atoms, in-situ doped epitaxial growth, and/or other suitable techniques. Of course, these examples are for illustrative purposes only and are not intended to be limiting.

In the present embodiments, the ML includes alternating silicon germanium (SiGe) and silicon (Si) layers arranged in a vertical stack along the Z axis and is configured to provide channel regions suitable for forming at least one GAA NFET and at least one GAA PFET. In the depicted embodiments, the bottommost layer of the ML is a SiGe layer 207 and the subsequent layers of the ML include alternating Si layers 205 and SiGe layers 207. In the present embodiments, the ML includes the same number of the Si layers 205 as the number of the SiGe layers 207. In some examples, the ML may include three to ten Si layers 205 and three to ten SiGe layers 207. In the present embodiments, each Si layer 205 includes elemental Si and is substantially free of Ge, while each SiGe layer 207 substantially includes both Si and Ge.

In the present embodiments, forming the ML includes alternatingly growing a SiGe layer (i.e., the SiGe layer 207) and a Si layer (i.e., the Si layer 205) in a series of epitaxy growth processes implementing chemical vapor deposition (CVD) techniques (for example, vapor-phase epitaxy (VPE), ultra-high vacuum CVD (UHV-CVD), low-pressure (LP-CVD), and/or plasma-enhanced CVD (PE-CVD)), molecular beam epitaxy, other suitable selective epitaxial growth (SEG) processes, or combinations thereof. The epitaxy process may use a gaseous and/or liquid precursor that interacts with the composition of the underlying substrate. For example, the substrate 202, which includes Si, may interact with a Ge-containing precursor to form the SiGe layer 207. In some examples, the Si layers 205 and the SiGe layers 207 may be formed into nanosheets, nanowires, or nanorods. In the present embodiments, the Si layers 205 and the SiGe layers 207 are each formed to substantially the same thickness T measured along the Z axis as depicted in FIG. 3A.

In the present embodiments, the Si layers 205 are configured as channel layers for forming the NFET and the PFET. A sheet (or wire) release process may then be implemented to form multiple openings between the corresponding channel layers, and a metal gate structure is subsequently formed in the openings to complete fabrication of the respective FETs.

Now referring to FIGS. 4A-4C, method 100 at operation 104 forms the fin 204 and the fin 206 over the substrate 202. In the depicted embodiments, the fins 204 and 206 are disposed adjacent and substantially parallel to each other, i.e., both oriented lengthwise along the X axis and spaced along the Y axis. As discussed in detail below, while the fins 204 and 206 are fabricated from the same ML and the substrate 202, they are, however, configured to provide GAA FETs of different conductivity type, i.e., one of the fins 204 and 206 is configured to provide an NFET and the other one of the fins 204 and 206 is configured to provide a PFET. In the depicted embodiments, the fin 204 is configured to provide an NFET and the fin 206 is configured to provide a PFET. Accordingly, the fin 204 may be formed in a region of the substrate 202 doped with a p-type dopant (i.e., a p-well structure) and the fin 206 may be formed in a region of the substrate 202 doped with an n-type dopant (i.e., an n-well structure). It is noted that embodiments of the device 200 may include additional fins (semiconductor fins) disposed over the substrate 202 configured to provide one or more NFETs and/or PFETs.

In the present embodiments, still referring to FIGS. 2A, 2B, and 4A-4C, each fin 204 includes the ML disposed over a base fin 204′ and each fin 206 includes the ML disposed over a base fin 206′, where the base fins 204′ and 206′ protrude from the substrate 202. The fins 204 and 206 may be fabricated using suitable processes including photolithography and etch processes. The photolithography process may include forming a masking element having a hard mask layer 220 over the ML, a hard mask layer 222 over the hard mask layer 220, a photoresist layer (resist; not depicted) over the hard mask layer 222, exposing the resist to a pattern, performing a post-exposure bake process to the resist, and developing the resist to form a patterned masking element exposing portions of the ML. The patterned masking element is then used for etching recesses into the ML and portions of the substrate 202, leaving the fins 204 and 206 protruding from the substrate 202. The hard mask layers 220 and 222 have different compositions and may each include silicon oxide, silicon nitride, silicon carbide, silicon oxynitride, silicon oxycarbide, other suitable materials, or combinations thereof. The etching process may include dry etching, wet etching, reactive ion etching (RIE), other suitable processes, or combinations thereof.

Numerous other embodiments of methods for forming the fins 204 and 206 may be suitable. For example, the fins 204 and 206 may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins 204 and 206.

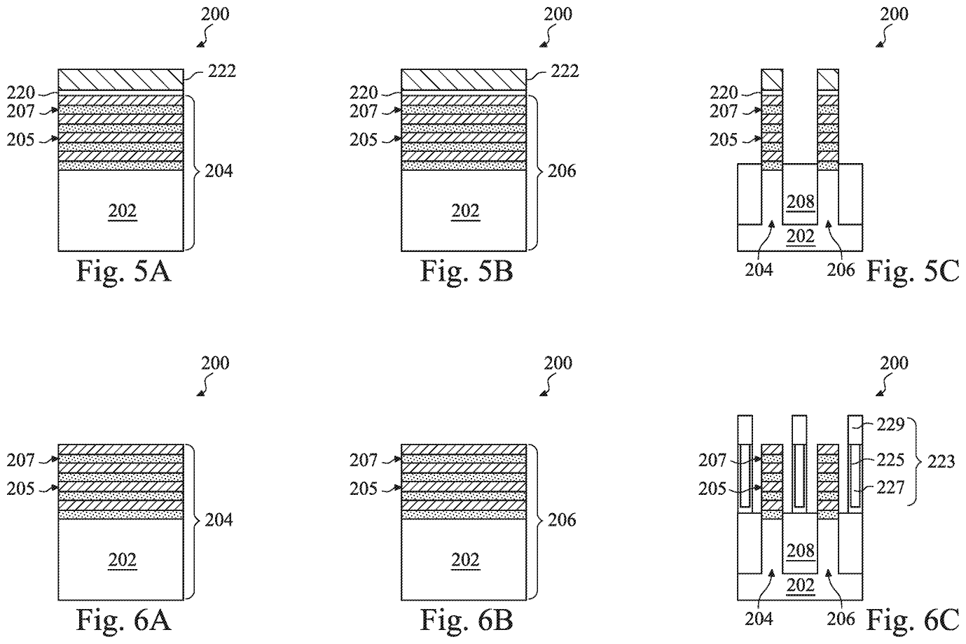

Referring to FIGS. 5A-5C, continuing with method 100 at operation 104 forms isolation structures 208 over the substrate 202 and separating bottom portions of the fins 204 and 206. The isolation structures 208 may include silicon oxide, fluoride-doped silicate glass (FSG), a low-k dielectric material, other suitable materials, or combinations thereof. In the present embodiments, the isolation structures 208 include shallow trench isolation (STI) features. In some embodiments, the isolation structures 208 are formed by depositing a dielectric layer over the substrate 202, thereby filling trenches between the fins 204 and 206, and subsequently recessing the dielectric layer such that a top surface of the isolation structures 208 is below a top surface of the fins 204 and 206, as depicted in FIG. 5C. Other isolation structures such as field oxide, local oxidation of silicon (LOCOS), other suitable structures, or combinations thereof may also be implemented as the isolation structures 208. In some embodiments, the isolation structures 208 may include a multi-layer structure, for example, having one or more thermal oxide liner layers. The isolation structures 208 may be deposited by any suitable method, such as CVD, flowable CVD (FCVD), spin-on-glass (SOG), other suitable methods, or combinations thereof.

Referring to FIGS. 6A-6C, continuing with method 100 at operation 104 forms dielectric fins 223 over the isolation structures 208, such that each of the fins 204 and 206 is disposed between two dielectric fins 223. Each dielectric fin 223 may be a single-layer structure or a multi-layer structure. In the present embodiments, the dielectric fin 223 is a tri-layer structure that includes a first layer 225 disposed on the isolation structures 208, a second layer 227 enclosed by the first layer 225, and a third layer 229 disposed over the first layer 225 and the second layer 227. The first layer 225, the second layer 227, and the third layer 229 may each include one or more dielectric materials, such as silicon oxide, silicon nitride, silicon carbide, silicon oxynitride, silicon oxycarbide, other suitable materials, or combinations thereof. In some embodiments, the first layer 225, the second layer 227, and the third layer 229 differ in composition. The dielectric fins 223 may be formed by any suitable process, including depositing and planarizing the first layer 225 over the device 200 to fill the space surrounding the fins 204 and 206, patterning (e.g., by a photolithography method) the first layer 225 to form trenches between the fins 204 and 206, depositing and planarizing the second layer 227 in the trenches, depositing the third layer 229 over the first layer 225 and the second layer 227, patterning the third layer 229 to expose portions of the first layer 225, and removing the exposed portions of the first layer 225 using the patterned third layer 229 as a hard mask. The first layer 225, the second layer 227, and the third layer 229 may be formed by any suitable deposition process, such as CVD, FCVD, ALD, other suitable processes, or combinations thereof. In the present embodiments, the dielectric fins 223 are configured to control the subsequent formation of n-type and p-type epitaxial S/D features over the fin 204 and the fin 206, respectively. In some examples, the dielectric fins 223 may prevent over-growth of epitaxial S/D features that inadvertently causes shorting in the device 200.

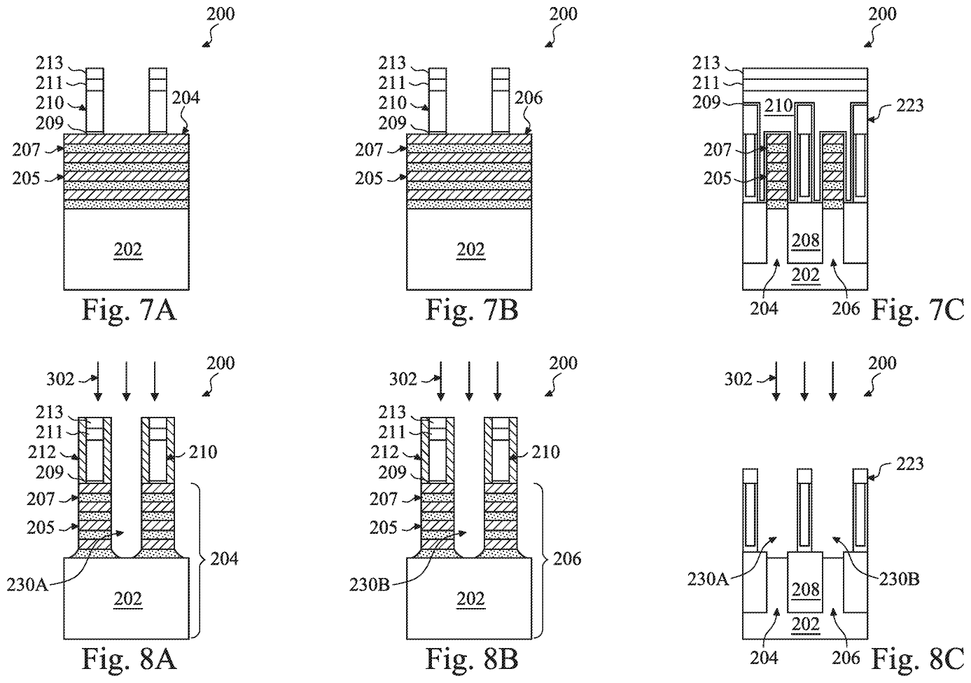

Now referring to FIGS. 7A-7C, continuing with method 100 at operation 104 forms a dummy gate stack (i.e., a placeholder gate) 210 over the channel region of each of the fins 204 and 206. In the present embodiments, portions of the dummy gate stack 210, which includes polysilicon, are replaced with a high-k (referring to a dielectric material having a dielectric constant greater than that of silicon oxide, which is about 3.9) metal gate structure (HKMG) after forming other components of the device 200. The dummy gate stack 210 may be formed by a series of deposition and patterning processes. For example, the dummy gate stack 210 may be formed by depositing a polysilicon layer over the fins 204 and 206, and subsequently performing an anisotropic etching process (e.g., a dry etching process) to leave portions of the polysilicon over the channel regions of the fins 204 and 206. In the present embodiments, the device 200 further includes an interfacial layer 209, which is formed on the fins 204 and 206 before depositing the dummy gate stack 210 by a suitable method, such as thermal oxidation, chemical oxidation, other suitable methods, or combinations thereof. In the depicted embodiments, a hard mask layer 211 and a hard mask layer 213 are formed over the dummy gate stack 210 to protect the dummy gate stack 210 from being etched during subsequent operations. The hard mask layers 211 and 213 may each include any suitable dielectric material discussed above with respect to the hard mask layers 220 and 222, and may be formed by a suitable deposition process, such as CVD, ALD, PVD, other suitable processes, or combinations thereof. The hard mask layers 211 and 213 are later removed before removing the dummy gate stack 210 to form the HKMG.

Thereafter, referring to FIGS. 8A-8C, method 100 at operation 106 performs a global etching process to form a S/D recess 230A in a S/D region of the fin 204 and a S/D recess 230B in a S/D region of the fin 206. Referring to FIGS. 8A and 8B, before forming the S/D recesses 230A and 230B, method 100 first forms top spacers 212 on sidewalls of the dummy gate stack 210. The top spacers 212 may be a single-layer structure or a multi-layer structure and may include silicon oxide, silicon nitride, silicon carbide, silicon oxynitride, silicon oxycarbide, other suitable materials, or combinations thereof. Each spacer layer of the top spacers 212 may be formed by first depositing a dielectric layer over the dummy gate stack 210 and subsequently removing portions of the dielectric layer in an anisotropic etching process (e.g., a dry etching process), leaving portions of the dielectric layer on the sidewalls of the dummy gate stack 210 as the top spacers 212.

Subsequently, still referring to FIGS. 8A-8C, method 100 removes portions of the ML in the S/D regions of the fins 204 and 206, exposing the substrate 202, by an etching process 302, which may be a dry etching process, a wet etching process, RIE, or combinations thereof. In the present embodiments, method 100 at operation 106 implements an etchant configured to remove the Si layers 205 and the SiGe layers 207. In other words, the etching process 302 is not selective to a particular material layer of the ML. In some examples, method 100 may implement a dry etching process using a chlorine-containing etchant (e.g., Cl₂, SiCl₄, BCl₃, other chlorine-containing gas, or combinations thereof), a bromine-containing etchant (e.g., HBr), other suitable etchants, or combinations thereof. In some embodiments, a depth of the S/D recesses 230A and 230B is controlled by adjusting duration, temperature, pressure, source power, bias voltage, bias power, etchant flow rate, other suitable parameters, or combinations thereof of the etching process 302. In the depicted embodiments, the etching process 302 is controlled such that the S/D recesses 230A and 230B expose portions of the substrate 202. A cleaning process may subsequently be performed to remove any etching residues in the S/D recesses 230A and 230B with hydrofluoric acid (HF) and/or other suitable solvents.

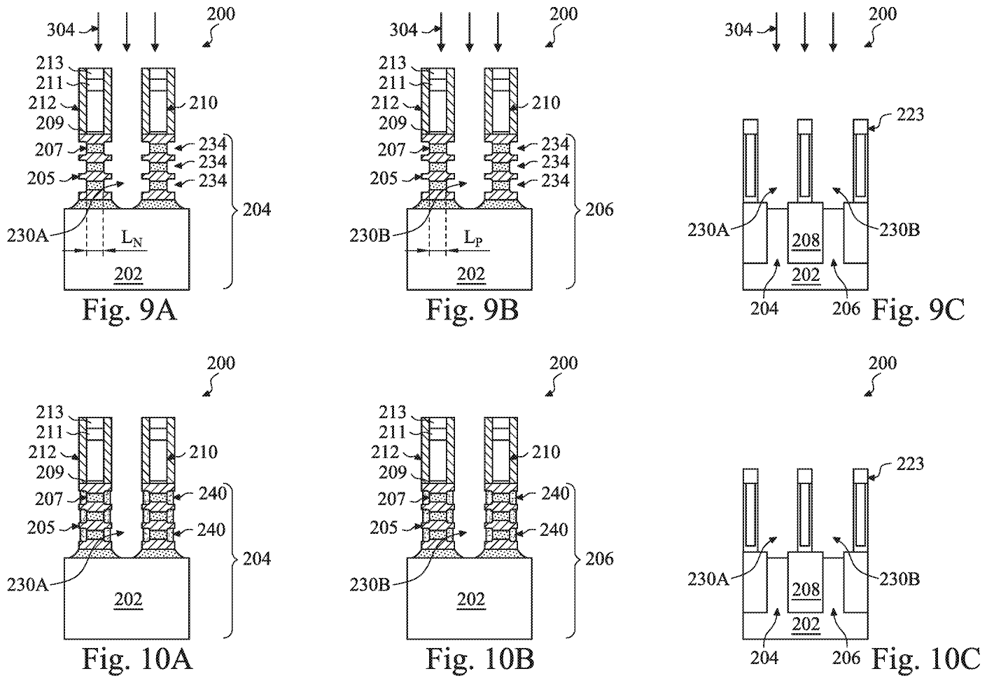

Collectively referring to FIGS. 9A-10C, method 100 at operations 108-110 forms inner spacers 240 on sidewalls of the non-channel layers in portions of the ML exposed in the S/D recesses 230A and 230B, respectively. In the present embodiments, the inner spacers 240 are configured to separate the epitaxial S/D features of the NFET and the PFET from their respective HKMGs formed between the channel layers.

Referring to FIGS. 9A-9C, method 100 at operation 108 selectively removes portions of the SiGe layers 207, which are configured as the non-channel layers of the NFET and PFET, to form recesses 234. Subsequently, method 100 implements an etching process 304 to selectively remove portions of the SiGe layers 207 exposed in the S/D recesses 230A and 230B without removing, or substantially removing, portions of the Si layers 205. In some embodiments, the etching process 304 is a wet etching process that implements hydrogen peroxide (H₂O₂), a hydroxide (e.g., ammonium hydroxide (NH₄OH), tetramethylammonium hydroxide (TMAH), etc.), acetic acid (CH₃COOH), other suitable etchants, or combinations thereof. In some embodiments, the etching process 304 is a dry etching process that implements a fluorine-containing etchant, such as HF, F₂, NF₃, other fluorine-containing etchants, or combinations thereof. In the present embodiments, the duration of the etching process 304 is controlled to ensure that only portions of each SiGe layer 207 are etched to form the recesses 234. In some embodiments, various parameters (e.g., the etchants used) of the etching process 304 are tuned to ensure high etching uniformity between the recesses 234, such that a gate length LN and LP for the NFET and PFET, respectively, may be controlled to a desired value between the Si layers 205.

Referring to FIGS. 10A-10C, method 100 at operation 110 forms the inner spacers 240 in the recesses 234. The inner spacers 240 may include any suitable dielectric material comprising silicon, carbon, oxygen, nitrogen, other elements, or combinations thereof. For example, the inner spacers 240 may include silicon nitride, silicon carbide, silicon oxide, carbon-containing silicon nitride (SiCN), carbon-containing silicon oxide (SiOC), oxygen-containing silicon nitride (SiON), carbon-and-oxygen-doped silicon nitride (SiOCN), a low-k dielectric material, tetraethylorthosilicate (TEOS), doped silicon oxide (e.g., borophosphosilicate glass (BPSG), fluoride-doped silicate glass (FSG), phosphosilicate glass (PSG), boron-doped silicate glass (BSG), etc.), air, other suitable dielectric material, or combination thereof. The inner spacers 240 may each be configured as a single-layer structure or a multi-layer structure including a combination of the dielectric materials provided herein. In some embodiments, the inner spacers 240 have a different composition from that of the top spacers 212. In some embodiments, the inner spacers 240 and the top spacers 212 have substantially the same composition. Method 100 may form the inner spacers 240 by depositing one or more dielectric layers in the recesses 234 via any suitable deposition process, such as ALD, CVD, other suitable methods, or combinations thereof, and subsequently performing one or more etching processes to remove any excess dielectric material formed on sidewalls of the channel layers (i.e., the Si layers 205).

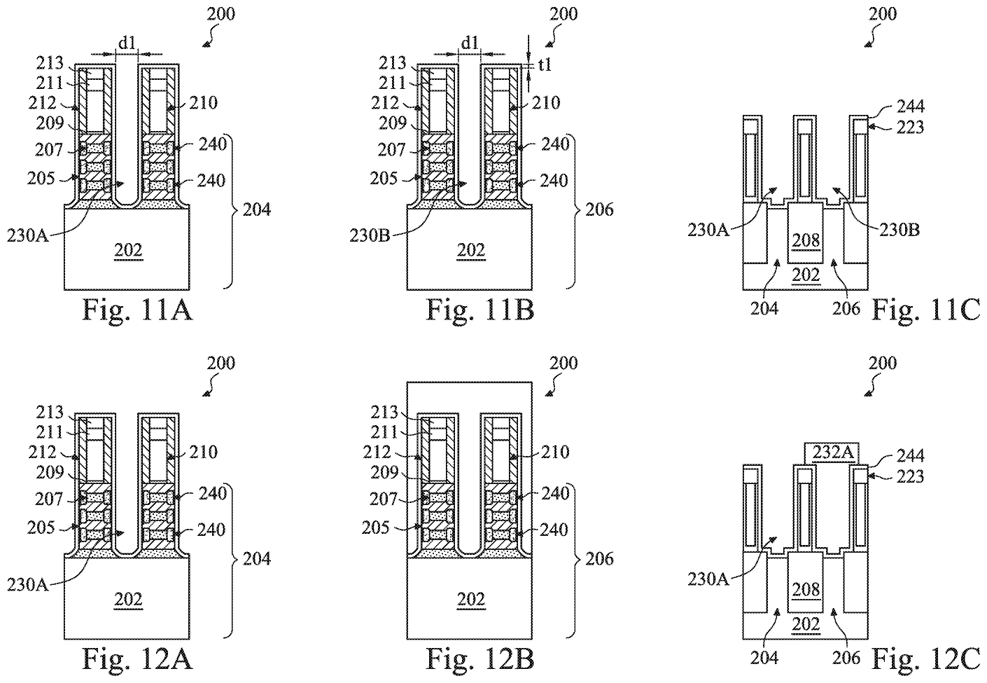

Referring to FIGS. 11A-11C, method 100 at operation 112 deposits a dummy layer 244 over device 200 including over fins 204 and 206 and on sidewalls and bottoms of S/D recesses 230A and 230B. Dummy layer 244 may be formed to prevent the unwanted growth of an epitaxial feature in a source/drain recess such as S/D recesses 230A and 230B, as will be described further below. For example, dummy layer 244 may be deposited in an n-type region (e.g., S/D recess 230A) to prevent the growth of a source/drain epitaxial feature in the NFET region during a p-type source/drain epitaxial growth process in the PFET region (e.g., S/D recess 230B). As the dimensions of the device 200 decrease, there is a need for the dummy layer 244 to be thin enough in order to avoid blocking the source/drain opening. Therefore, material and deposition method thereof for forming the dummy layer 244 should not be arbitrarily picked. For example, a nitride-containing layer may generally be about 10 nm to about 20 nm thick which may cause the nitride-containing dummy layer to merge and block the source/drain opening when used as the material for the dummy layer 244. As illustrated in FIGS. 11A and 11B, there is a distance d1 between a first portion of dummy layer 244 disposed on a first dummy gate 210 and a second portion of dummy layer 244 dispose on a second dummy gate 210. Distance d1 may be about 7 nm to about 11 nm. If distance d1 is less than 7 nm, then it may be difficult to open the source/drain recess using a subsequent etching process. In the depicted embodiment, a metal-containing material that is suitable for atomic layer deposition (ALD) for better thickness control is used for forming the dummy layer 244. In one instance, the metal-containing material is aluminum oxide (AlOx). The thinner metal-containing material increases the distance d1 as compared to nitride-containing material. Dummy layer 244 including AlOx may mitigate the problems caused by using other material such as SiN. In some embodiments, the ALD of AlOx is carried out in a hot-wall flow-type reactor from the sequential pulse of TMA and O3 under 30-50 Pa at room temperature for about 3 to 10 ALD cycles. Consequently, the dummy layer 244 has a thickness t1 that is about 3 atomic layers to about 10 atomic layers of AlOx. The number of atomic layers of AlOx provides a good compromise between thin film durability and limited available space in an S/D recess. If the thickness of the dummy layer 244 is than less than 3 atomic layers of AlOx, the dummy layer 244 may be too thin to survive from subsequent processes. If the thickness of the dummy layer 244 is more than 10 atomic layers of AlOx, the opening of the S/D recesses 230A and 230B may become unnecessarily narrow.

Referring to FIGS. 12A-12C, method 100 at operation 114 deposits a photoresist layer 232A over the PFET region including over fin 206 and in S/D recess 230B. Photoresist layer 232A may be formed over dummy layer 244 in S/D recess 230B as well as over a portion of the top surface of dielectric fin 223 between S/D recess 230A and S/D recess 230B. Photoresist layer 232A has a different etch rate than dummy layer 244. Photoresist layer 232A may include any suitable photoresist material. In some embodiments, photoresist layer 232A may include a bottom anti-reflective coating (BARC) layer.

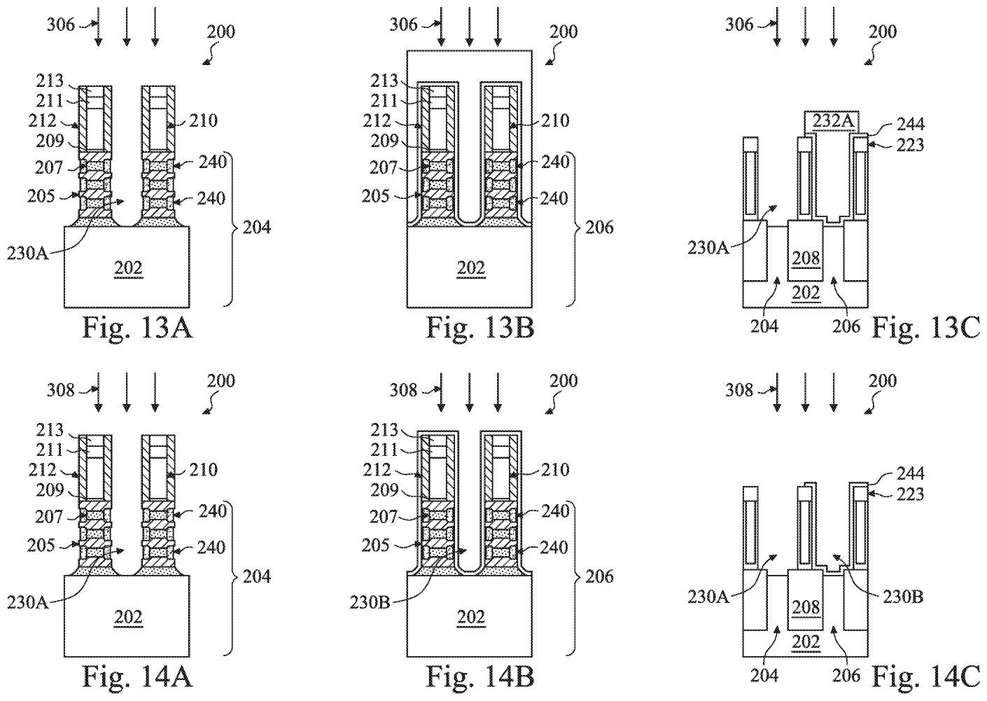

Referring to FIGS. 13A-13C, method 100 at operation 116 removes dummy layer 244 from the NFET region including the S/D recess 230A using an etching process 306. The etching process 306 may be a dry etch, a wet etch, or a combination. In the depicted embodiment, the dummy layer 244 contains AlOx and wet etching process may be used. The wet etching process may include the use of an ammonia and hydrogen peroxide mixture (APM) such as SC1 solution (NH₄OH:H₂O_{2:}H₂O) or a buffer of hydrofluoric acid such as HF/NH₃F with a ratio of about 1:6. An exemplary dry etch process may include a fluorine-containing gas (e.g., CF₄, SF₆, CH₂F₂, CHF₃, NF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, a small amount of residue of dummy layer 244 may remain in S/D recess 230A after the etching process 306 is complete, particularly in corner regions in the S/D recess 230A, such as the footings of the dielectric fins 223 where the etchants are generally more difficult to reach.

Referring to FIGS. 14A-14C, method 100 at operation 118 removes the photoresist layer 232A from over the PFET region, including from over fin 206, using etching process 308. The etching process 308 may include dry etching, wet etching, reactive ion etching (RIE), other suitable processes, or combinations thereof. In some embodiments, when photoresist layer 232A includes BARC, a plasma ashing process may be used to remove photoresist layer 232A. In some other embodiments, a photoresist stripping process may be used.

Now referring to FIGS. 15A-15C, method 100 at operation 120 forms an n-type epitaxial S/D feature 250 in each S/D recess 230A. Each of the n-type epitaxial S/D features 250 is configured to form an NFET with the subsequently formed HKMG. The n-type epitaxial S/D features 250 may include one or more epitaxial layers of silicon (epi Si) or silicon carbon (epi SiC) doped with an n-type dopant such as arsenic, phosphorus, other n-type dopants, or combinations thereof. In the present embodiments, dummy layer 244 protects the fin 206 while exposing the fin 204 before forming the n-type epitaxial features 250. In the present embodiments, one or more epitaxy growth processes are performed to grow an epitaxial material in each S/D recess 230A. For example, method 100 may implement an epitaxy growth process as discussed above with respect to forming the Si layers 205 and the SiGe layers 207 of the ML. The epitaxial growth process may be performed at a temperature of about 650° C. to about 750° C. In some embodiments, the temperature during the n-type epitaxial growth process may be about 700° C. The high temperature used during the epitaxial growth process may improve the quality of S/D feature 250 as compared to using a lower temperature. Additionally, the high temperature may harden dummy layer 244 in the PFET region, including in S/D recess 230B. In some embodiments, the epitaxial material is doped in-situ by adding a dopant to a source material during the epitaxy growth process. In some embodiments, the epitaxial material is doped by an ion implantation process after performing a deposition process. In some embodiments, an annealing process is subsequently performed to activate the dopants in the n-type epitaxial S/D features 250.

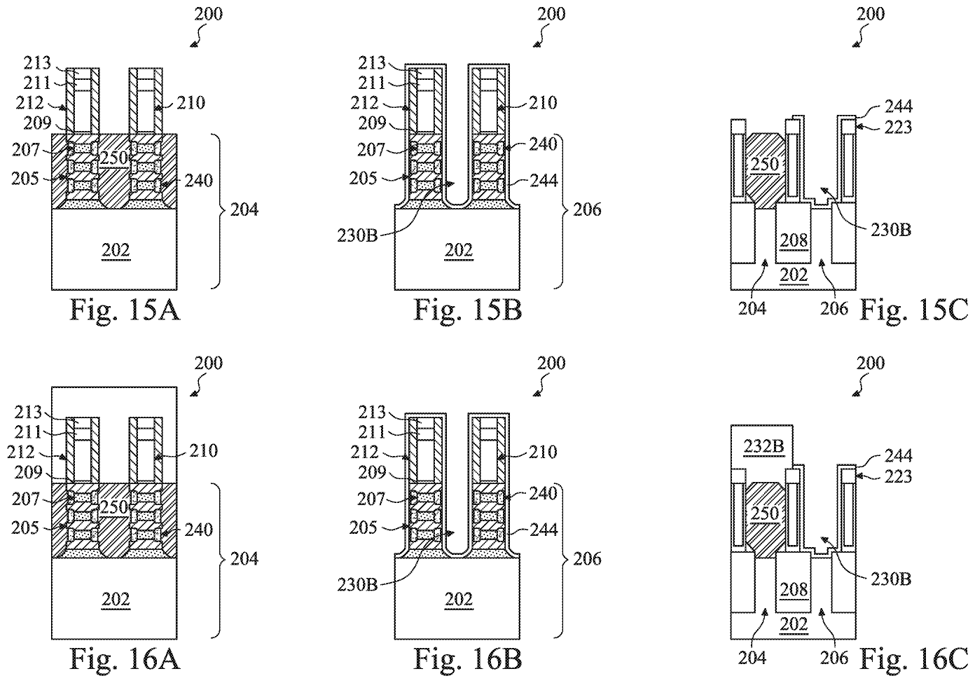

Referring to FIGS. 16A-16C, method 100 at operation 122 deposits a photoresist layer 232B over the NFET region, including over S/D feature 250. Photoresist layer 232B protects S/D feature 250 in a subsequent etching process, described below. Photoresist layer 232B may be formed similar to photoresist layer 232A, described above.

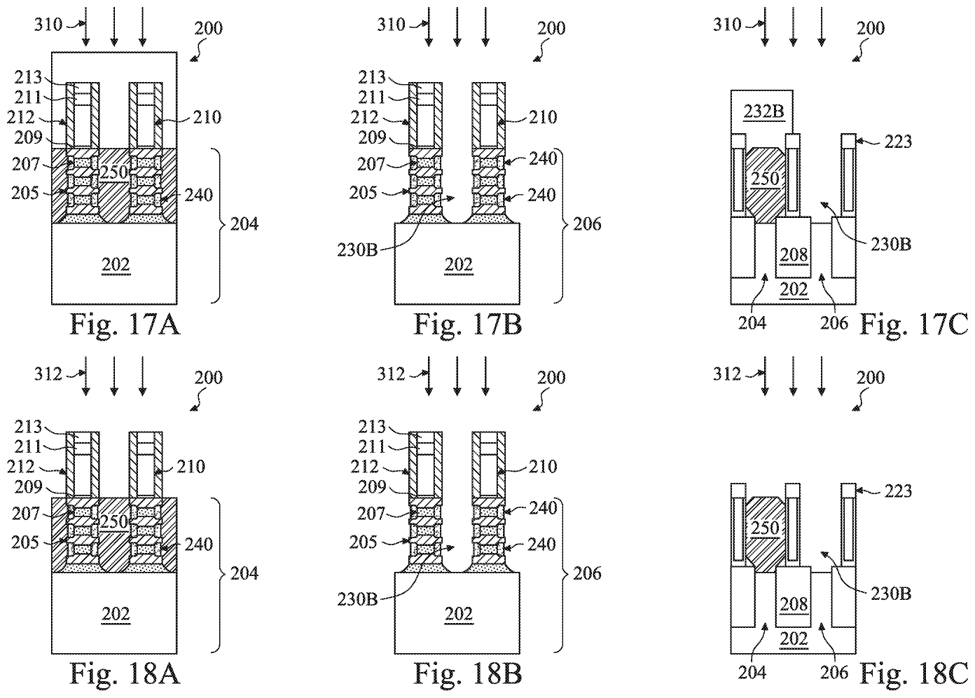

Referring to FIGS. 17A-17C, method 100 at operation 124 removes the dummy layer 244 from the PFET region, including from S/D recess 230B, using an etching process 310. The etching process 310 may be the same as described above with respect to etching process 306. After performing etching process 310, residue from dummy layer 244 may remain in S/D recess 230B. In some embodiments, more residue of dummy layer 244 may remain in S/D recess 230B than residue that remained in S/D recess 230A. This is because of the higher temperature used during n-type epitaxial growth process, as described above with respect to FIGS. 15A-15C, which caused dummy layer 244 to harden.

Referring to FIGS. 18A-18C, method 100 at operation 126 removes the photoresist layer 232B from the NFET region, including from over S/D feature 250, using etching process 312. The etching process 312 may be similar to etching process 308, described above with respect to removing photoresist layer 232A.

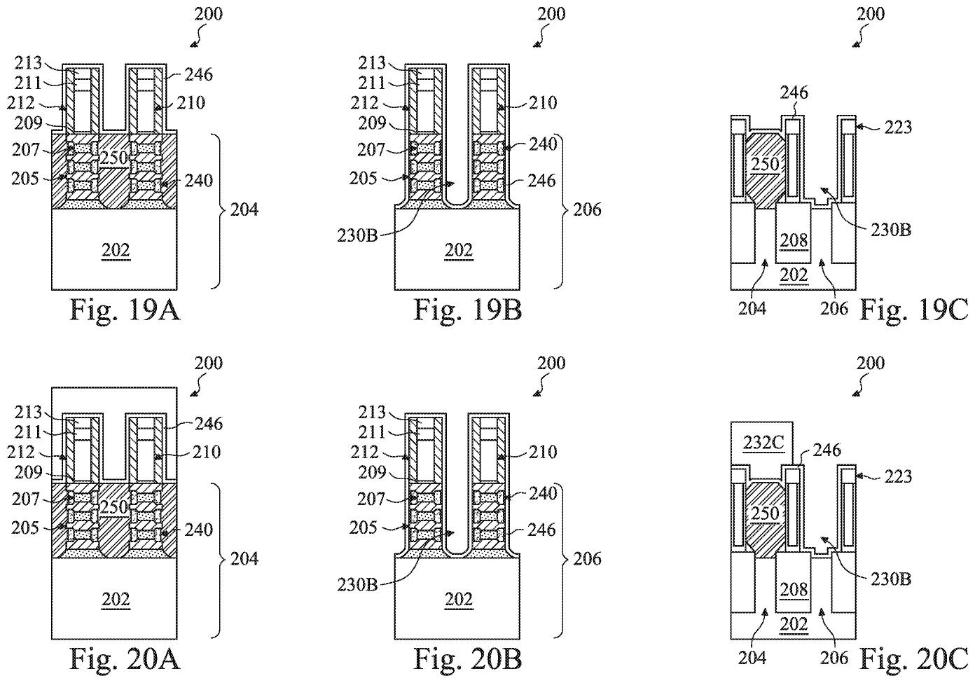

Referring to FIGS. 19A-19C, method 100 at operation 128 deposits a dummy layer 246 over device 200, including over S/D feature 250 an over S/D recess 230B. Dummy layer 246 may be deposited in a similar as described above with respect to dummy layer 244. Dummy layer 246 may be made of similar materials as dummy layer 244, as described above. In the depicted embodiment, dummy layer 246 includes AlOx. In some embodiments, the ALD of AlOx of dummy layer 246 may be carried out in a hot-wall flow-type reactor from the sequential pulse of TMA and O₃ under 30-50 Pa at room temperature for about 4 to 12 ALD cycles. Consequently, dummy layer 246 may have a thickness of about 4 atomic layers to about 12 atomic layers. The additional thickness may ensure the strength and uniformity of deposition of dummy layer 246. This may prevent defects from forming a hole that may expose S/D feature 250.

Referring to FIGS. 20A-20C, method 100 at operation 130 deposits a photoresist layer 232C over the NFET region, including over dummy layer 246 that is disposed over S/D feature 250. Photoresist layer 232C is also deposited over dielectric fin 223 that is disposed between fin 204 and fin 206. Photoresist layer 232C protects dummy layer 246 in the NFET region during a subsequent etching process, described below.

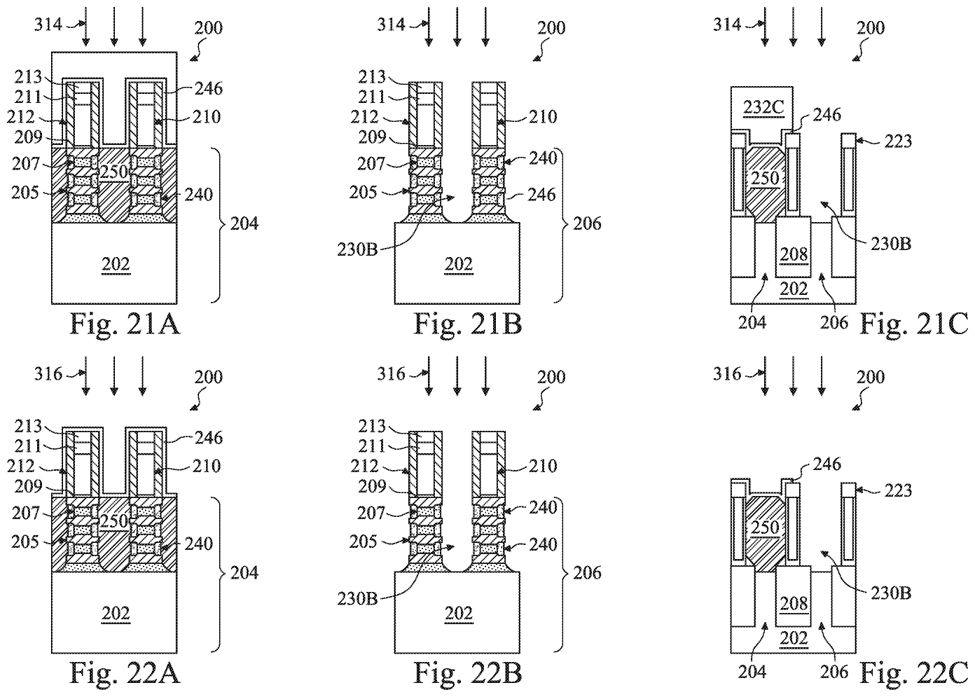

Referring to FIGS. 21A-21C, method 100 at operation 132 removes dummy layer 246 from the PFET region, including from S/D recess 230B, using an etching process 314. The etching process 314 removes dummy layer 246 with little to no effect to photoresist layer 232C. The etching process 314 may be similar to the etching process 306 described above with respect to removing dummy layer 244. More of dummy layer 246 may be removed than dummy layer 244 because dummy layer 246 was not subjected to the high temperature process that dummy layer 244 was subjected to.

Referring to FIGS. 22A-22C, method 100 at operation 134 removes photoresist layer 232C from the NFET region using etching process 316. The etching process 316 exposes the remaining portions of dummy layer 246 that were protected by photoresist layer 232C. The etching process 316 may be similar to that described above with respect to etching process 308. The etching process 316 may remove all of photoresist layer 232C with little to no etching of dummy layer 246.

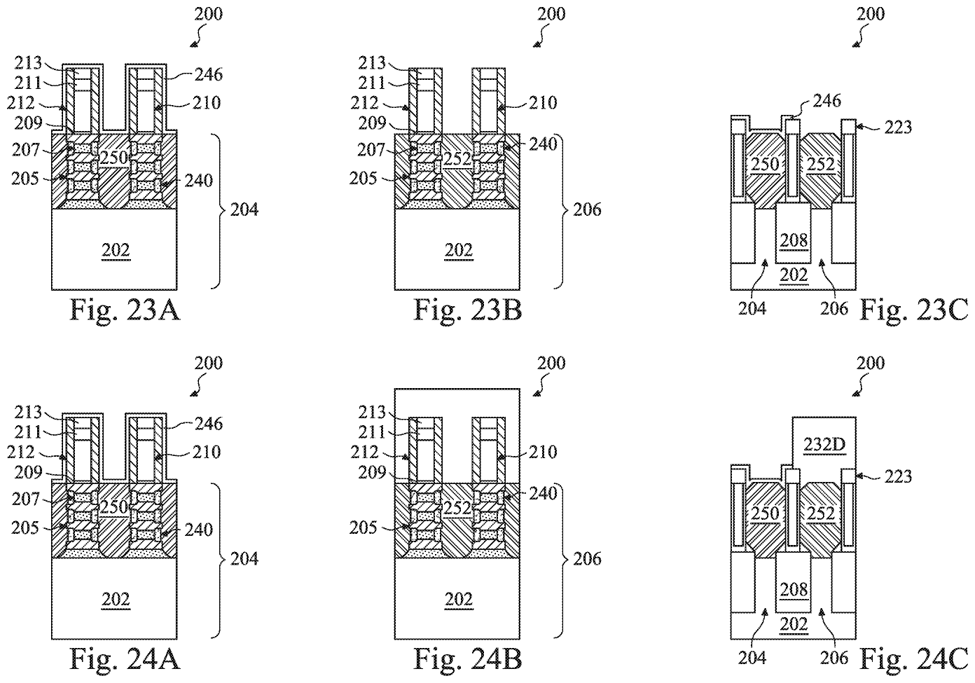

Subsequently, referring to FIGS. 23A-23C, method 100 at operation 136 forms a p-type epitaxial S/D feature 252 in each S/D recess 230B. Each of the p-type epitaxial S/D features 252 is configured to form a PFET with the subsequently formed HKMG. The p-type epitaxial S/D features 252 may include one or more epitaxial layers of silicon germanium (epi SiGe) doped with a p-type dopant such as boron, germanium, indium, other p-type dopants, or combinations thereof. In the present embodiments, dummy layer 246 protects the fin 204 while exposing the fin 206 during formation of the p-type epitaxial S/D features 252. In the present embodiments, the p-type epitaxial S/D features 252 are formed and doped in one or more epitaxy growth and doping processes discussed above with respect to forming the n-type epitaxial features 250. Temperatures during the epitaxy growth of the p-type S/D features 252 may be about 550° C. to about 650° C. In some embodiments, the temperature during the epitaxy growth of the p-type S/D features 252 may be about 600° C. The temperature during the epitaxy growth of the p-type S/D features 252 is lower than the temperature during the epitaxy growth of the n-type S/D features 250. Subjecting the p-type S/D features 252 to a higher temperature may damage the p-type S/D features 250. For this reason, the n-type S/D features 250 are formed before the p-type S/D features 252 as opposed the conventional process of forming the p-type source/drain features first. This method and process improve the quality and performance of both n-type S/D features 250 and p-type S/D features 252 by reducing stress in the p-type S/D features 252 caused by the higher temperatures of the n-type epitaxy growth process.

Referring to FIGS. 24A-24C, method 100 at operation 138 deposits a photoresist layer 232D over the PFET region including over S/D feature 252, leaving dummy layer 246 disposed in the NFET region exposed. Photoresist layer 232D may be deposited similar to the process described above with respect to photoresist layer 232A.

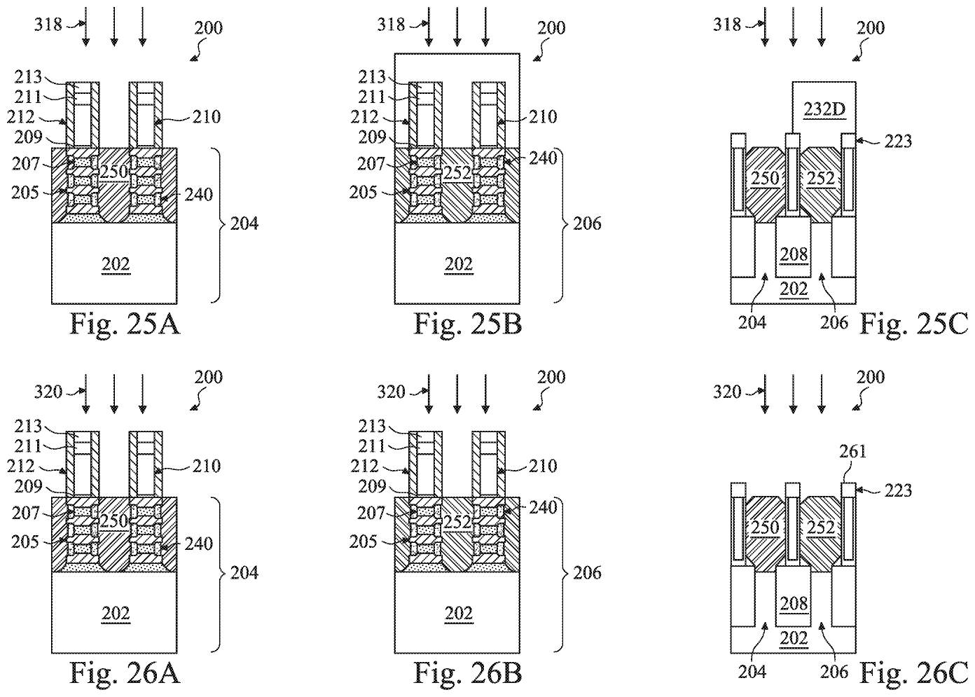

Referring to FIGS. 25A-25C, method 100 at operation 140 removes dummy layer 246 from the NFET region using an etching process 318. The etching process 318 may be similar to the process described above with respect to etching process 306. The etching process 318 may remove dummy layer 246 with little to no etching of S/D features 250.

Referring to FIGS. 26A-26C, method 100 at operation 142 removes photoresist layer 232D from the PFET region using etching process 320. The etching process 320 may be similar to process described above with respect to the etching process 308. The etching process 320 may remove photoresist layer 232D with little to no etching of S/D feature 252.

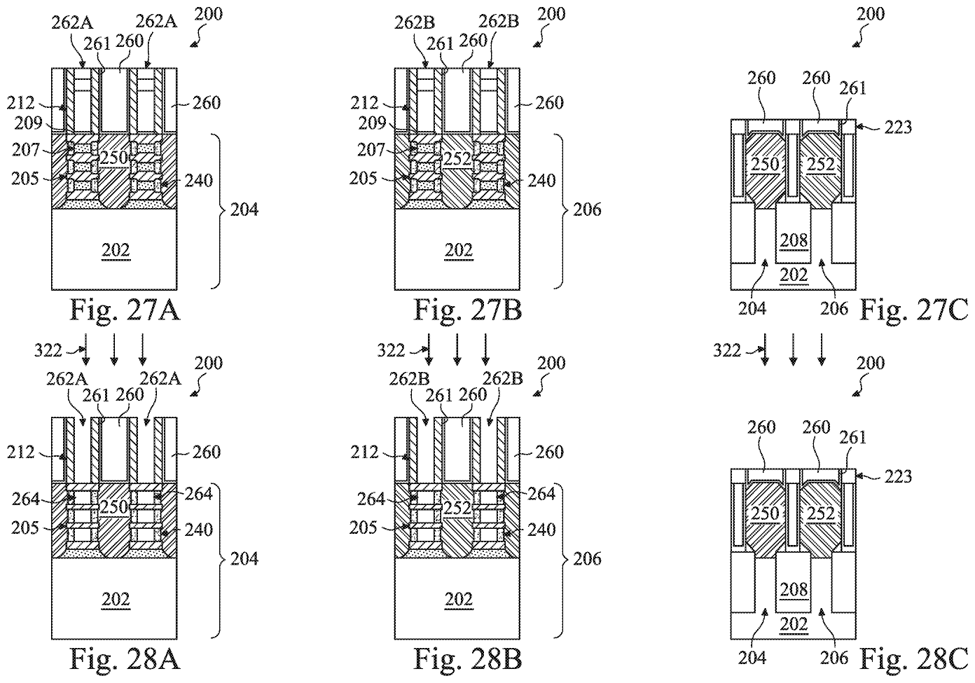

Referring to FIGS. 27A-27C, method 100 at operation 144 forms an inter level dielectric (ILD) layer 260 over device 200. ILD layer 260 may be formed over the n-type epitaxial S/D features 250 and the p-type epitaxial S/D features 252 by, for example, CVD, FCVD, other suitable methods, or combinations thereof. The ILD layer 260 may include silicon oxide, a low-k dielectric material, TEOS, doped silicon oxide (e.g., BPSG, FSG, PSG, BSG, etc.), other suitable dielectric materials, or combinations thereof. In some embodiments, as depicted in FIGS. 27A-27C, method 100 first forms an etch-stop layer (ESL) 261 over the n-type epitaxial S/D features 250 and the p-type epitaxial S/D features 252 before forming the ILD layer 260. The ESL 261 may include silicon nitride, silicon carbide, carbon-containing silicon nitride (SiCN), oxygen-containing silicon nitride (SiON), carbon-and-oxygen-doped silicon nitride (SiOCN), aluminum nitride, a high-k dielectric material, other suitable materials, or combinations thereof, and may be formed by CVD, ALD, PVD, other suitable methods, or combinations thereof. Subsequently, method 100 may planarize the ESL 261 and the ILD layer 260 in one or more CMP processes to expose a top surface of the dummy gate stack 210.

Collectively referring to FIGS. 28A-28C, method 100 at operations 146 remove dummy gates 262A and 262B as well as SiGe layers 207 in a sheet formation process, thereby forming openings 264 between the Si layers 205 in the fins 204 and 206. The etching process 322 may include dry etching, wet etching, RIE, or combinations thereof. Accordingly, the etching process 322 removes the SiGe layers 207 with little to no etching of the Si layers 205, which are substantially free of Ge. Of course, other suitable etching processes different from the etching process 322 may also be applicable, so long as they are effective at selectively removing the SiGe layers 207 with respect to the Si layers 205. In the present embodiments, the etching process 322 is controlled to ensure that all of the SiGe layers 207 are removed from the fins 204 and 206, such that the openings 264 are formed between the Si layers 205, which are the channel layers of the NFET and PFET. Subsequent to or concurrent with the removal of the SiGe layers 207, method 100 at operation 126 removes portions of the interfacial layer 209 disposed over the channel region of the fins 204 and 206.

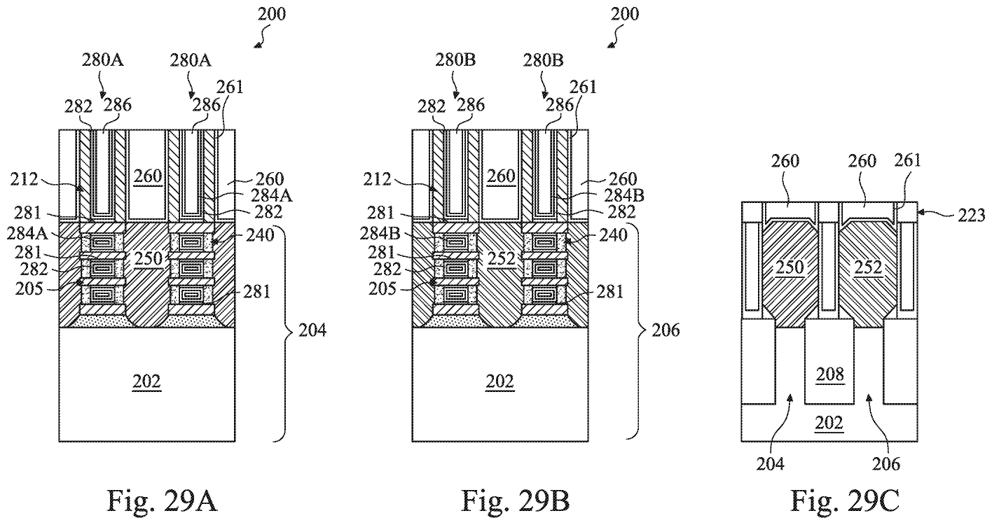

Now referring to FIGS. 29A-29C, method 100 at operation 148 forms a HKMG 280A over the channel region of the fin 204 to form the NFET and a HKMG 280B over the channel region of the fin 206 to form the PFET. In the present embodiments, top portions of the HKMGs 280A and 280B are formed in the gate trenches 262A and 262B, respectively, and bottom portions of the HKMGs 280A and 280B are formed in the openings 264 and 266, respectively.

In the present embodiments, the HKMGs 280A and 280B each include at least a high-k dielectric layer 282 disposed over and surrounding the channel layers of the NFET and the PFET and a metal gate electrode disposed over the high-k dielectric layer 282. In the present embodiments, the high-k dielectric layer 282 includes any suitable high-k dielectric material, such as hafnium oxide, lanthanum oxide, other suitable materials, or combinations thereof. In the present embodiments, the metal gate electrode of the HKMG 280A includes at least a work function metal (WFM) layer 284A disposed over the high-k dielectric layer 282 and a conductive layer 286 disposed over the WFM layer 284A, and the metal gate electrode of HKMG 280B includes at least a WFM layer 284B disposed over the high-k dielectric layer 282 and the conductive layer 286 disposed over the WFM layer 284B. The WFM layer 284A and the WFM layer 284B may each be a single-layer structure or a multi-layer structure including at least a p-type WFM layer, an n-type WFM layer, or a combination thereof. The conductive layer 286 may include Cu, W, Al, Co, Ru, other suitable materials, or combinations thereof. In the depicted embodiments, the HKMGs 280A and 280B each includes an interfacial layer 281 formed between each channel layer and the high-k dielectric layer 282. The HKMGs 280A and 280B may further include other layers (not depicted), such as a capping layer, a barrier layer, other suitable layers, or combinations thereof. In some embodiments, the number of material layers included in each of the HKMGs 280A and 280B is determined by the size of the openings 264 and 266, respectively. Various layers of the HKMGs 280A and 280B may be formed by any suitable method, such as chemical oxidation, thermal oxidation, ALD, CVD, PVD, plating, other suitable methods, or combinations thereof.

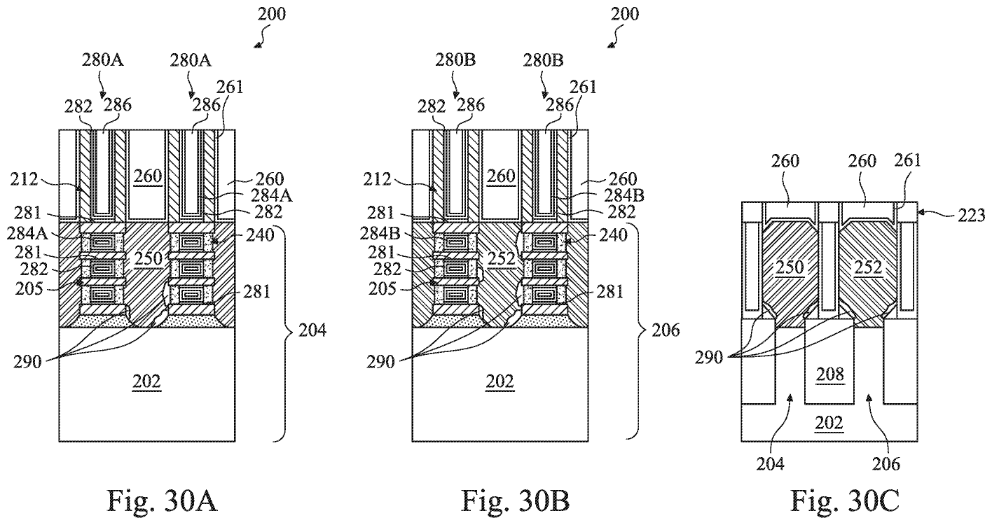

Now referring to FIGS. 30A-30C, illustrated are exemplary devices after finishing processing according to the steps of method 100. As described above, residue 290 of the dummy layers 244 and 246 may remain in S/D recesses 230A and 230B after the etching process have been performed to remove dummy layers 244 and 246. Residue 290 may have little, to no effect, on the formation of S/D features 250 and 252. Residue 290 may be discernable by examining concentration of aluminum atoms using tunnel electron microscopy (TEM) imaging or scanning electron microscopy (SEM). Depicted in FIGS. 30A-30C are exemplary and illustrative residue 290 of dummy layers 244 and 246. The illustration is not intended to be accurate in either size or location of the residue. The illustration is to be used for the purposes of discussion about residue 290. For example, as discussed above, the n-type epitaxy growth process may harden dummy layer 244 in S/D recess 230B. The hardened dummy layer 244 may be more difficult to remove than the dummy layer 244 from S/D recess 230A which was not hardened by high temperatures. The hardened dummy layer 244 may be more difficult to remove than dummy layer 246 that was presented during the lower temperature p-type epitaxy growth process. This difference is illustrated in FIGS. 30A and 30B by the fact that there is more residue 290 in the PFET region, FIG. 30B, than in the NFET region, FIG. 30A. In some embodiments, there may be similar amount of residue 290 in both NFET and PFET regions. Further, in each of the NFET region and PFET region, a higher concentration of aluminum atom may be found at footings of the dielectric fins 223 under the epitaxial S/D features 250 and 252 than on sidewalls elsewhere, as illustrated in FIG. 30C. This is mainly due to corner regions being more difficult for etchants to reach in the S/D recesses 230A and 230B during the removal of the dummy layers 244 and 246. In some instances, a concentration of aluminum atom at footings of the dielectric fins 223 in the PFET region may be 2 times to 3 times of that at footings of the dielectric fins 223 in the NFET region. In some other embodiments, there may be no residue 290 in the NFET region and/or the PFET region. The amount and/or location of residue 290 may vary from one wafer to another wafer as well as from one region of a wafer to another region of the same wafer.

The present disclosure provides for many different embodiments. An exemplary method of receiving a substrate including a n-type region and a p-type region, forming a stack of semiconductor layers over the substrate, the stack of semiconductor layers including interleaving first material layers and second material layers, and performing an etch process to form a first source/drain recess in the n-type region and a second source/drain recess in the p-type region. The method further includes depositing a metal-containing layer over the stack of semiconductor layers, including within the first source/drain recess and the second source/drain recess, removing the metal-containing layer from the n-type region, and forming an n-type epitaxial source/drain feature in the first source/drain recess. The method further includes removing the metal-containing layer from the p-type region and forming a p-type epitaxial source/drain structure in the second source/drain recess.

Another exemplary method includes receiving a stack of semiconductor layers disposed over a substrate including a first region and a second region, forming a first source/drain recess in the first region, and forming a second source/drain recess in the second region. The method further includes depositing a first metal-containing layer over the second source/drain recess, forming a first epitaxial structure in the first source/drain recess, and depositing a second metal-containing layer over the first source/drain recess. The method further includes forming a second epitaxial structure in the second source/drain recess.

An exemplary semiconductor device includes a plurality of semiconductor layers vertically stacked above a substrate, an epitaxial source/drain structure abutting the plurality of semiconductor layers, and first and second dielectric fins sandwiching the epitaxial source/drain structure. The semiconductor device further includes a gate structure wrapping around each of the semiconductor layers and aluminum residue disposed at footings of the first and second dielectric fins and under the epitaxial source/drain structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a substrate including a n-type region and a p-type region;
forming a stack of semiconductor layers over the substrate, the stack of semiconductor layers including interleaving first material layers and second material layers;
performing an etch process to form a first source/drain recess in the n-type region and a second source/drain recess in the p-type region;
depositing a metal-containing layer over the stack of semiconductor layers, including within the first source/drain recess and the second source/drain recess;
removing the metal-containing layer from the n-type region;
forming an n-type epitaxial source/drain feature in the first source/drain recess;
removing the metal-containing layer from the p-type region; and
forming a p-type epitaxial source/drain structure in the second source/drain recess.

2. The method of claim 1, wherein the metal-containing layer is a first metal-containing layer and the method further includes depositing a second metal-containing layer over the n-type epitaxial source/drain feature and the p-type source/drain recess.

3. The method of claim 2, further comprising:
depositing a first photoresist layer over the p-type region, including in the second source/drain recess;
after the removing of the metal-containing layer from the n-type region, removing the first photoresist layer from the p-type region;
forming a third photoresist layer over the n-type region;
removing the second metal-containing layer form the p-type source/drain recess; and
removing the third photoresist layer from the n-type region.

4. The method of claim 3, further comprising:
after forming the p-type epitaxial source/drain feature, forming a fourth photoresist layer over the p-type region;
removing the second metal-containing layer from the n-type region; and
removing the fourth photoresist layer from the p-type region.

5. The method of claim 3, wherein forming the first photoresist layer includes forming a bottom anti-reflective coating layer.

6. The method of claim 1, wherein the metal-containing layer is aluminum oxide.

7. The method of claim 1, wherein the forming the n-type epitaxial source/drain feature is performed at a temperature of about 650° C. to about 750° C., hardening the metal-containing layer.

8. A method, comprising:
receiving a stack of semiconductor layers disposed over a substrate including a first region and a second region;
forming a first source/drain recess in the first region;
forming a second source/drain recess in the second region;
depositing a first metal-containing layer over the second source/drain recess;
forming a first epitaxial structure in the first source/drain recess;
depositing a second metal-containing layer over the first source/drain recess; and
forming a second epitaxial structure in the second source/drain recess.

9. The method of claim 8, wherein the depositing the first metal-containing layer over the second source/drain recess further includes:
depositing the first metal-containing layer over the first source/drain recess and the second source/drain recess;
forming a photoresist layer over the second source/drain recess;
removing the metal layer from the first source/drain recess; and
removing the photoresist layer.

10. The method of claim 8, wherein the depositing second metal-containing layer over the first source/drain recess further includes:
depositing the second metal-containing layer over the second source/drain recess;
forming a photoresist layer over the first source/drain recess;
removing the metal layer from the second source/drain recess; and
removing the photoresist layer from the first source/drain recess.

11. The method of claim 8, wherein the depositing the first metal-containing layer includes depositing aluminum oxide having a thickness of about 3 to about 10 atomic layers.

12. The method of claim 8, wherein the forming the first epitaxial source/drain feature further includes forming a n-type epitaxial source/drain feature.

13. The method of claim 8, wherein the forming the second epitaxial source/drain feature further includes forming a p-type epitaxial source/drain feature.

14. The method of claim 8, further comprising:
before depositing the second metal-containing layer, removing the first metal-containing layer from over the second source/drain recess.

15. A semiconductor device, comprising:
a plurality of semiconductor layers vertically stacked above a substrate;
an epitaxial source/drain structure abutting the plurality of semiconductor layers;
first and second dielectric fins sandwiching the epitaxial source/drain structure;
a gate structure wrapping around each of the semiconductor layers; and
aluminum residue disposed at footings of the first and second dielectric fins and under the epitaxial source/drain structure.

16. The semiconductor device of claim 15, wherein the plurality of semiconductor layers is a first plurality of semiconductor layers, the epitaxial source/drain structure is a first epitaxial source/drain structure, and wherein the semiconductor device further includes:
a second plurality of semiconductor layers vertically stacked above the substrate;
a second epitaxial source/drain structure abutting the second plurality of semiconductor layers;
third and fourth dielectric fins sandwiching; and
aluminum residue disposed at footings of the third and fourth dielectric fins and under the second epitaxial source/drain structure.

17. The semiconductor device of claim 16,
wherein an amount of aluminum residue under the first epitaxial source/drain structure is less than that under the second epitaxial source/drain structure.

18. The semiconductor device of claim 17, wherein the first epitaxial source/drain structure is a n-type epitaxial source/drain structure and the second epitaxial source/drain structure is a p-type epitaxial source/drain structure.

19. The semiconductor device of claim 15, further comprising:
inner spacers interposing the epitaxial source/drain structure and the gate structure, wherein the aluminum residue is also disposed between the epitaxial source/drain structure and the inner spacers.

20. The semiconductor device of claim 19, wherein the aluminum residue includes aluminum oxide.
